(19) United States
(12) Patent Application Publication
(10) Pub. No.: US 2026/0181997 A1
(43) Pub. Date: Jun. 25, 2026

(54) ILD WITH HIGH ETCHING SELECTIVITY FOR FORMING CONTACT PLUGS

(71) Applicant: Taiwan Semiconductor Manufacturing Co., Ltd., Hsinchu (TW)

(72) Inventors: Rui-Fu Chen, Hsinchu (TW); Hsin Yang Hung, New Taipei City (TW); Szu-Hua Chen, Tainan City (TW); Tsung-Kai Chiu, Hsinchu (TW); Shih-Jung Ho, Hsinchu (TW)

(21) Appl. No.: 19/195,980

(22) Filed: May 1, 2025

Related U.S. Application Data
(60) Provisional application No. 63/738,061, filed on Dec. 23, 2024.

(51) Int. Cl. H10D 84/01; H01L 21/02; H10D 84/83

(52) U.S. Cl. CPC H10D 84/013; H10D 84/0149; H10D 84/832; H10P 70/27

(57) ABSTRACT

A method includes forming a first semiconductor layer and a second semiconductor layer overlapping the first semiconductor layer. The second semiconductor layer is spaced apart from the first semiconductor layer by a dielectric isolation layer. The method further includes performing a first epitaxy process to form a lower source/drain region aside of the first semiconductor layer, forming a dummy contact etch stop layer over the lower source/drain region, forming a dummy inter-layer dielectric over the dummy contact etch stop layer, and performing a second epitaxy process to form an upper source/drain region aside of the second semiconductor layer, The upper source/drain region is over the dummy inter-layer dielectric. The dummy inter-layer dielectric and the dummy contact etch stop layer are removed to form a gap between the upper source/drain region and the lower source/drain region. A dielectric region is formed to fill the gap.

### PRIORITY CLAIM AND CROSS-REFERENCE

This application claims the benefit of the following provisionally filed U.S. Patent application: Application No. 63/738,061, filed on Dec. 23, 2024, and entitled “CFET SiOC ILD0 for MDLI Sidewall Silicide,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2-5, 6A, 6B, 7A, 7B, 8A, 8B, 9A, 9B, 10A, 10B, 11A, 11B, 12A, 12B, 13A, 13B, 14A, 14B, 15A, 15B, 16A and 16B are views of intermediate stages in the fabrication of CFETs in accordance with some embodiments.

FIG. 17 illustrates a process flow for fabricating the CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) and the methods of forming the same are provided. In accordance with some embodiments, a lower source/drain region, a dummy Contact Etch Stop Layer (CESL), a dummy Inter-Layer Dielectric (ILD), and an upper source/drain region are formed. The dummy ILD is formed of a first dielectric material such as silicon oxide. The dummy CESL and the dummy ILD are then removed. A first CESL and a second CESL are then formed, followed by the formation of a first ILD and a second ILD. The first ILD and the second ILD are formed of a second dielectric material different from the first dielectric material of the dummy ILD. The second dielectric material is more resistance to the chemical(s) used in a subsequent pre-clean process, which is performed prior to the formation of silicide layers. Accordingly, the bowing (protruding) of source/drain contact plugs into the first ILD is avoided.

It is appreciated that while Gate-All-Around (GAA) transistors (such as nanostructure-FETs) are discussed as examples, the concept of the present disclosure can also be applied to the formation of other types of transistors such as planar transistors, Fin Field-Effect Transistors (FinFETs), or the like. Throughout the description, the terms “FET” and “transistor” are used interchangeably.

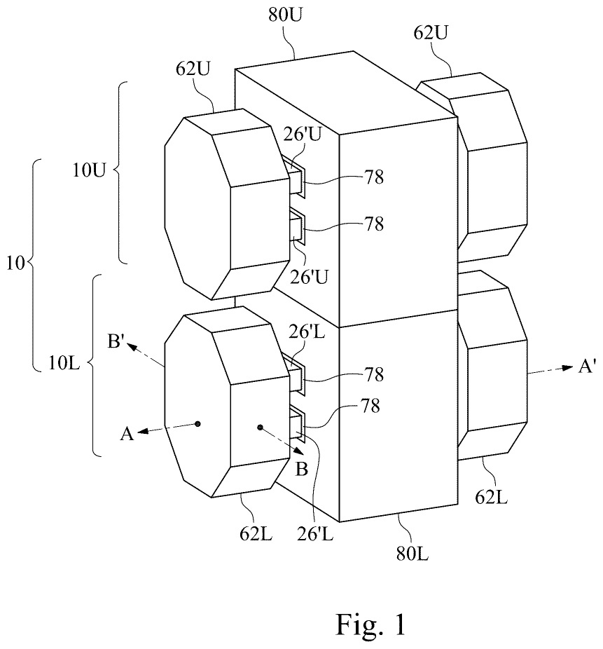

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

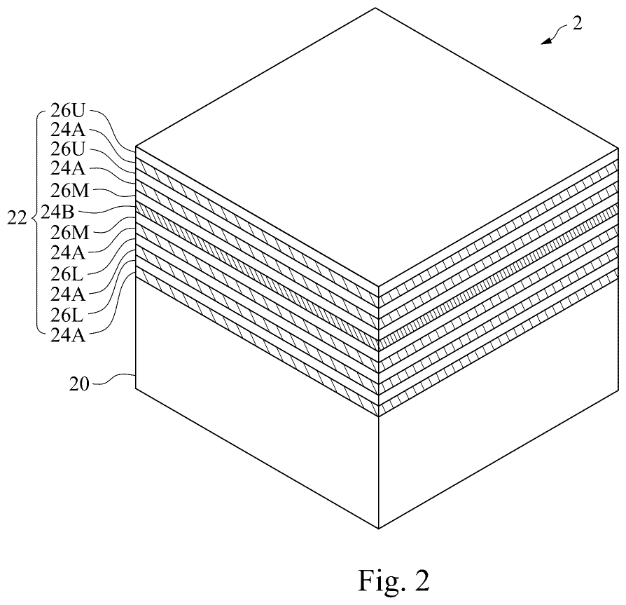

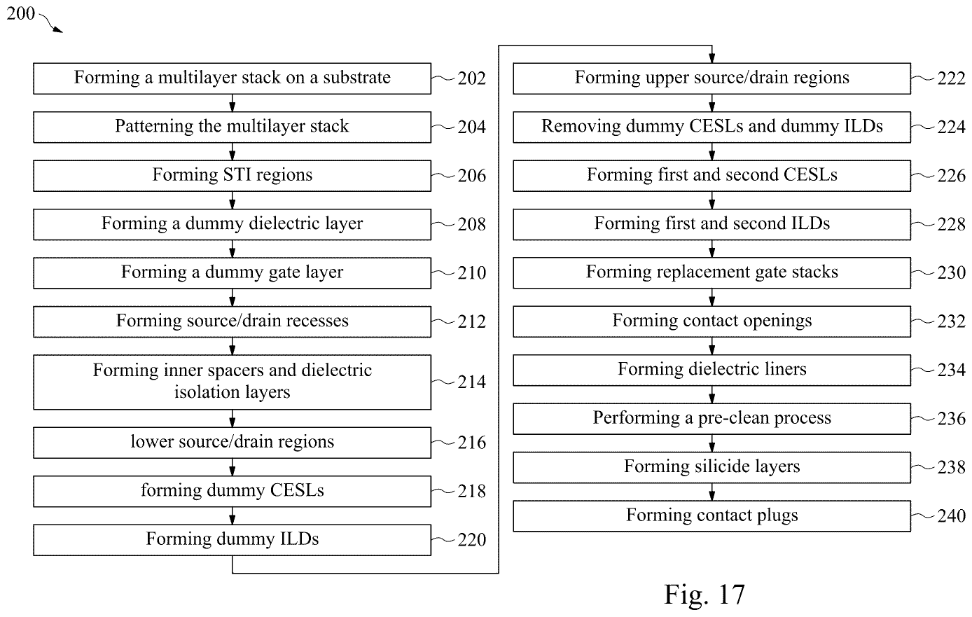

FIGS. 2-5, 6A, 6B, 7A, 7B, 8A, 8B, 9A, 9B, 10A, 10B, 11A, 11B, 12A, 12B, 13A, 13B, 14A, 14B, 15A, 15B, 16A and 16B illustrate the cross-sectional views of intermediate stages in the formation of CFETs (as schematically represented in FIG. 1) in accordance with some embodiments. The corresponding processes are also reflected schematically in the process flow 200 as shown in FIG. 17. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor; or the like, or combinations thereof.

A multilayer stack 22 is formed over the substrate 20. The respective process is illustrated as process 202 in the process flow 200 as shown in FIG. 17. The multilayer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

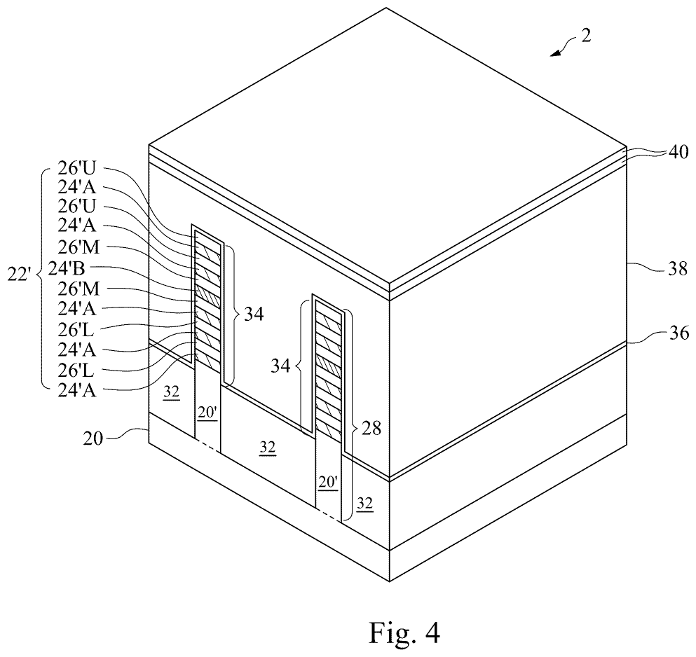

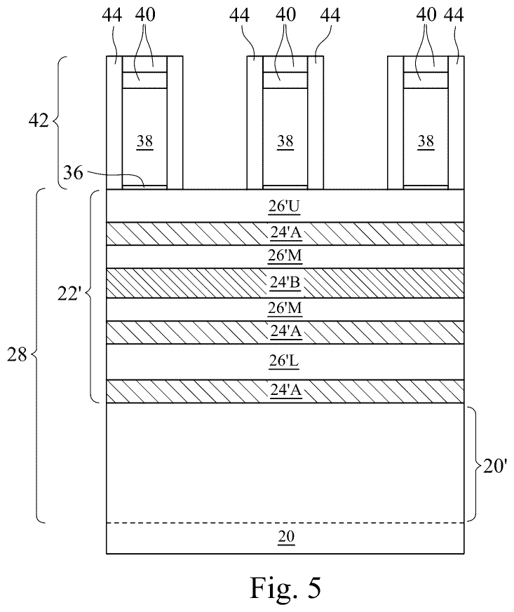

In the illustrated example as shown in FIG. 2, the multilayer stack 22 includes three lower semiconductor layers 26L and two upper semiconductor layers 26U. It should be appreciated that the multilayer stack 22 may include any number of the dummy semiconductor layers 24A and the semiconductor layers 26U and 26L. For example, FIG. 5 shows an example in which the multilayer stack 22 includes one lower semiconductor layer 26L and one upper semiconductor layer 26U as an example, which is different from that shown in FIG. 4. Each layer of the multilayer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

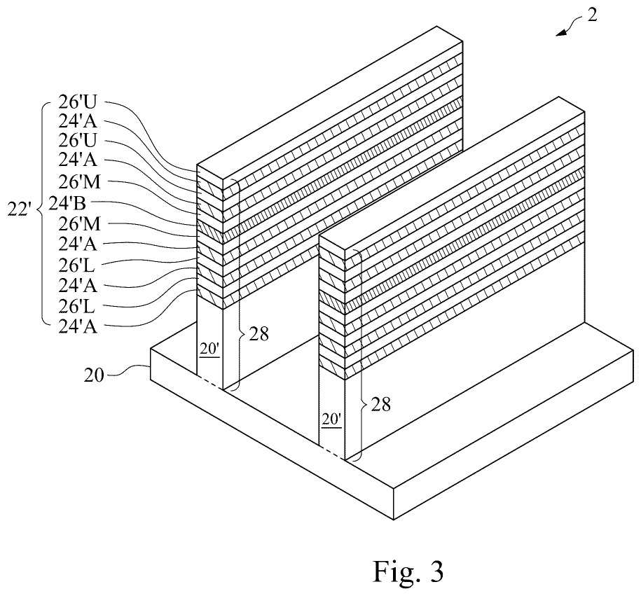

In FIG. 3, multilayer stack 22 and substrate 20 are patterned to form semiconductor strips 28. The respective process is illustrated as process 204 in the process flow 200 as shown in FIG. 17. Each of semiconductor strips 28 includes semiconductor strip 20′ (the portions of the original substrate 20) and multilayer stack 22′, which is the remaining portion of multilayer stack 22. The remaining portions 22′ of multilayers stack 22 are referred to as nanostructures hereinafter, which are referred to using the corresponding reference number followed by a “′” sign. Accordingly, multilayer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

In FIG. 4, isolation regions 32 are formed over the substrate 20 and between adjacent semiconductor strips 28. The respective process is illustrated as process 206 in the process flow 200 as shown in FIG. 17. Isolation regions 32 may include a dielectric liner and a dielectric material over the dielectric liner. Isolation regions 32 are then recessed. Some upper portions of semiconductor strips 28 (including multilayer stacks 22′) protrude higher than the remaining isolation regions 32 to form protruding fins 34.

Dummy dielectric layer 36 is then formed on the protruding fins 34. The respective process is illustrated as process 208 in the process flow 200 as shown in FIG. 17. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 210 in the process flow 200 as shown in FIG. 17. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42. The multilayer stack 22′ may include any number of the dummy semiconductor layers 24′A and the semiconductor layers 26′U and 26′L.

In FIG. 5, gate spacers 44 are formed over the multilayer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

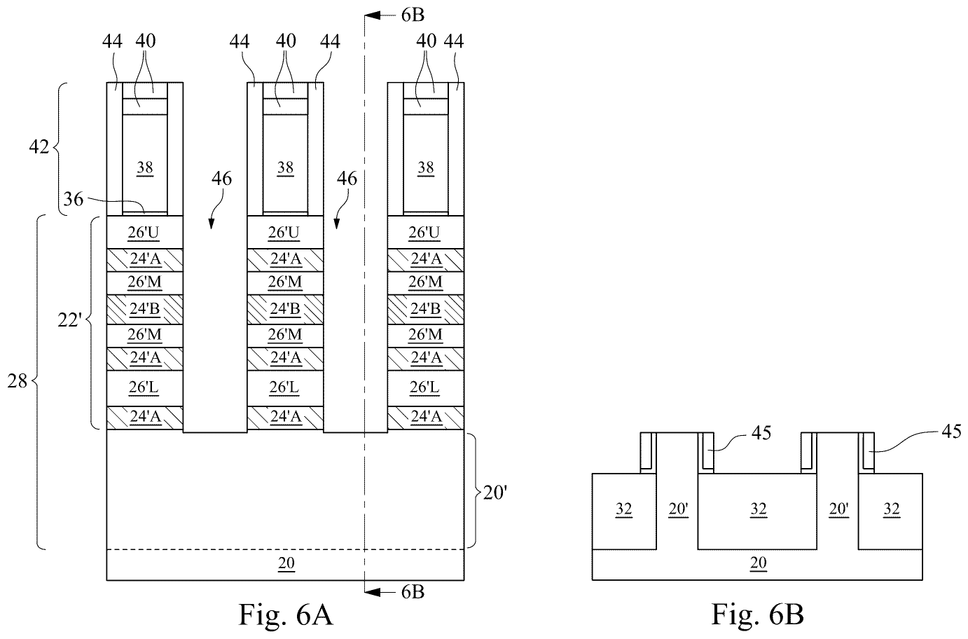

Referring to FIGS. 6A and 6B, source/drain recesses 46 are formed in semiconductor strips 28. The respective process is illustrated as process 212 in the process flow 200 as shown in FIG. 17. FIG. 6B illustrates a cross-section 6B-6B as shown in FIG. 6A. The source/drain recesses 46 are formed through etching, and may extend through the multilayer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes.

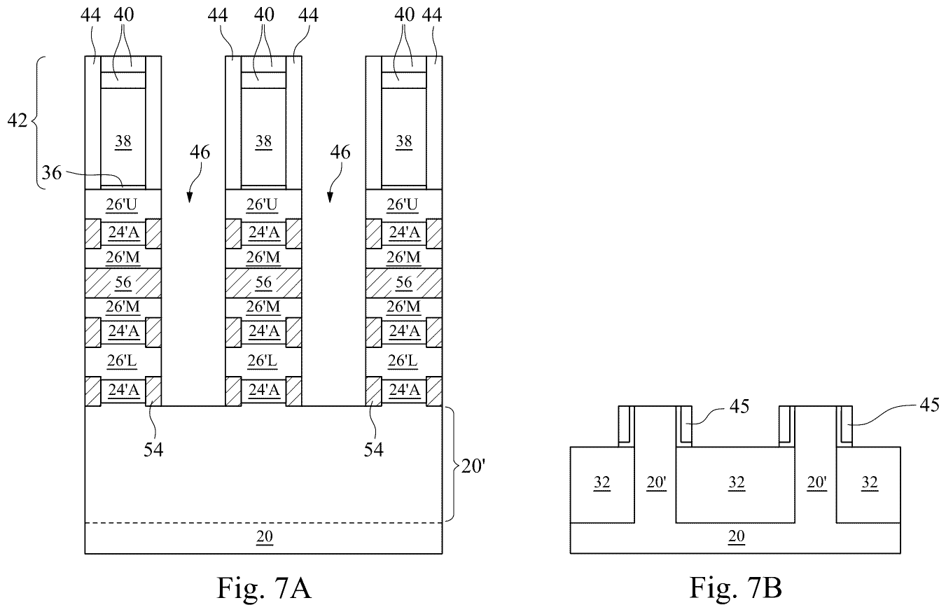

Referring to FIGS. 7A and 7B, dummy nanostructures 24′A are laterally recessed, and a dielectric material is filled into the respective recesses to form inner spacers 54, which are dielectric spacers. Dielectric isolation layers 56 are also formed to replace the dummy nanostructures 24′B. The respective processes are illustrated as process 214 in the process flow 200 as shown in FIG. 17.

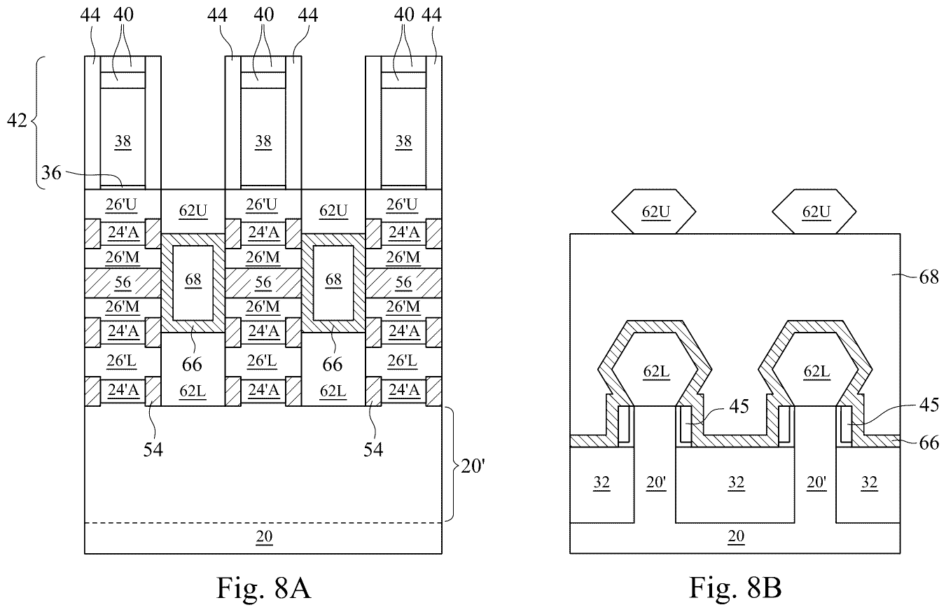

Next, as shown in FIGS. 8A and 8B, lower source/drain regions 62L are formed in the lower portions of the source/drain recesses 46 (FIG. 5). The respective process is illustrated as process 216 in the process flow 200 as shown in FIG. 17. The lower source/drain regions 62L are in contact with the lower semiconductor nanostructures 26′L and are not in contact with the upper semiconductor nanostructures 26′U. Inner spacers 54 electrically insulate the lower source/drain regions 62L from the dummy nanostructures 24′A, which will be replaced with replacement gates in subsequent processes.

The lower (epitaxial) source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants.

In accordance with some embodiments, a dummy contact etch stop layer (CESL) 66 may be formed over lower source/drain regions 62L. The respective process is illustrated as processes 218 in the process flow 200 as shown in FIG. 17. The dummy CESL 66 may be formed of silicon nitride, silicon oxide, silicon oxynitride, or the like, which may be formed by any suitable deposition process, such as CVD, ALD, or the like.

Dummy ILD 68 is formed over dummy CESL 66. The respective process is illustrated as processes 220 in the process flow 200 as shown in FIG. 17. Dummy ILD 68 may be formed of a dielectric material, which may be deposited by any suitable method, such as FCVD, plasma-enhanced CVD (PECVD), or CVD. The applicable dielectric material of the dummy ILD 68 may include silicon oxide, phospho-silicate glass (PSG), boro-silicate glass (BSG), boron-doped phospho-silicate glass (BPSG), undoped silicate glass (USG), or the like. Dummy ILD 68 and dummy CESL 66 collectively form a dummy dielectric region that is to be removed in subsequent processes.

The formation processes of dummy ILD 68 and dummy CESL 66 may include depositing a conformal CESL layer, depositing a material for ILD 68, followed by a planarization process and then an etch-back process. In accordance with some embodiments, the dummy ILD 68 is etched first, leaving the dummy CESL 66 unetched. An isotropic etching process is then performed to remove the portions of the dummy CESL 66 higher than the recessed dummy ILD 68. After the recessing, the sidewalls of the upper semiconductor nanostructures 26′U are exposed.

In accordance with alternative embodiments, instead of forming dummy CESL 66 and dummy ILD 68, a homogeneous dielectric material is formed as the dummy dielectric region. The homogeneous dielectric material may be selected from the same group of materials for forming dummy ILD 68.

Next, upper source/drain regions 62U are formed in the upper portions of the source/drain recesses 46. The respective process is illustrated as process 222 in the process flow 200 as shown in FIG. 17. The materials of upper source/drain regions 62U may be selected from the same candidate group of materials for forming lower source/drain regions 62L, depending on the desired conductivity type of upper source/drain regions 62U.

The conductivity type of the upper source/drain regions 62U may be opposite the conductivity type of the lower source/drain regions 62L. Alternatively stated, the upper source/drain regions 62U may be oppositely doped from the lower source/drain regions 62L. The upper source/drain regions 62U may be in-situ doped, and/or may be implanted, with an n-type or p-type dopant.

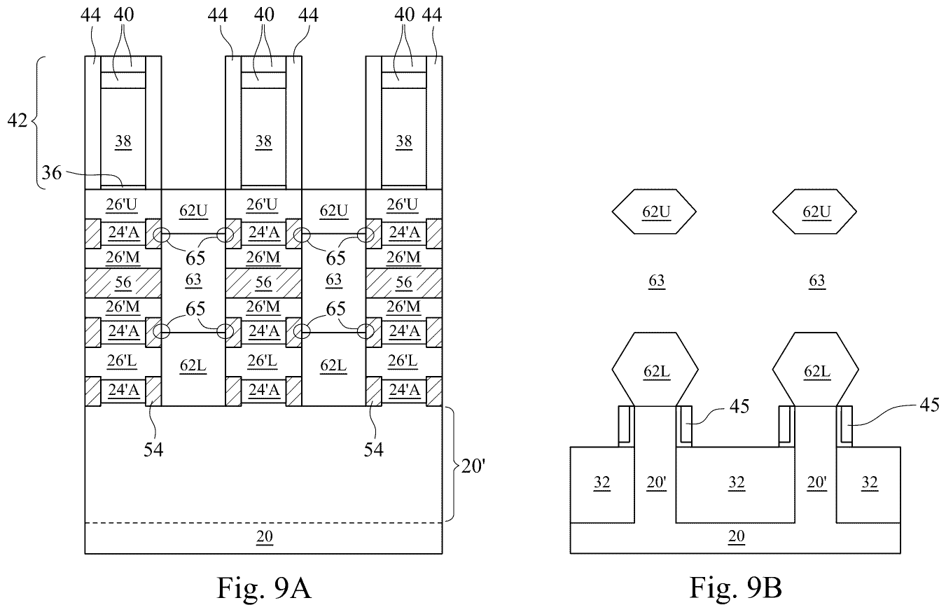

Referring to FIGS. 9A and 9B, an etching process(es) is performed to remove dummy CESL 66 and dummy ILD 68. The respective process is illustrated as process 224 in the process flow 200 as shown in FIG. 17. The etching may include an isotropic etching process(es), which may be a dry etching process(es) and/or a wet etching process(es). After the etching, voids (also referred to as gaps or air gaps) 63 are formed to separate upper source/drain regions 62U from the respective lower source/drain regions 62L.

In accordance with some embodiments, dummy ILD 68 and dummy CESL 66 are fully removed. In accordance with alternative embodiments, some residue portions of dummy CESL 66 may be left at corner regions 65 as shown in FIG. 9A.

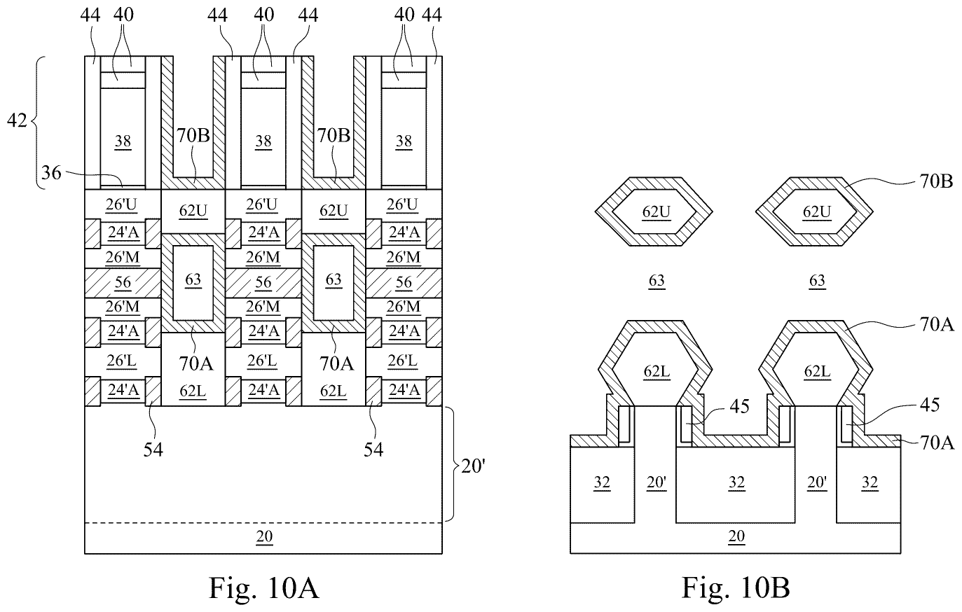

Next, as shown in FIGS. 10A and 10B, CESLs 70A and 70B are formed. The respective process is illustrated as process 226 in the process flow 200 as shown in FIG. 17. CESLs 70 are also referred to as replacement CESLs. CESLs 70A and 70B are formed in a same formation process, and may be formed of a dielectric material having a high etching selectivity from the etching of the subsequently formed ILDs 72A and 72B. For example, CESLs 70A and 70B may be formed of or comprise as silicon nitride, silicon oxide, silicon oxynitride, or the like, which may be formed by any suitable conformal deposition process, such as CVD, ALD, or the like.

Referring to FIG. 10, CESLs 70A may be formed as full rings including top portions (which may be horizontal portions) contacting the bottom surfaces of upper source/drain regions 62U, and bottom portions (which may be horizontal portions) contacting the respective underlying lower source/drain regions 62L.

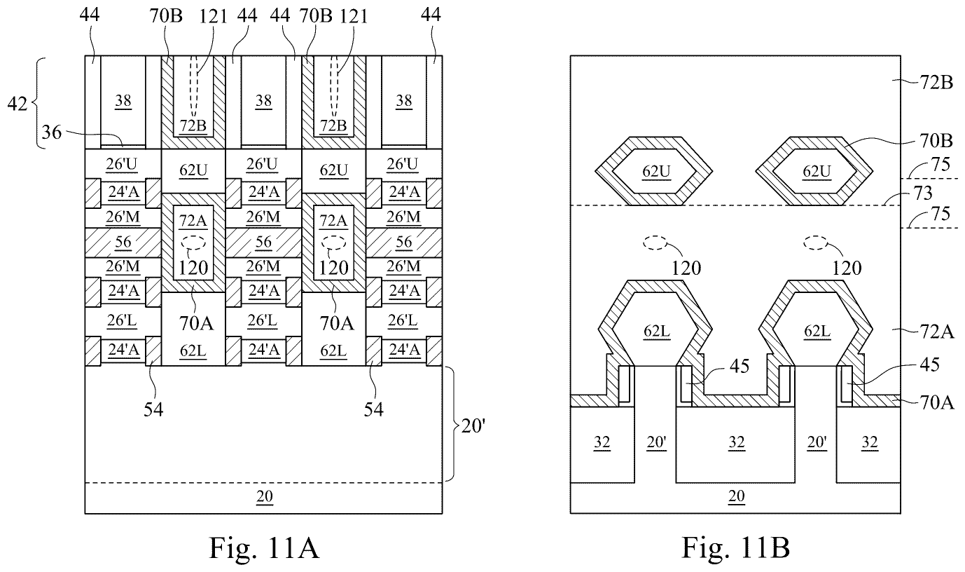

Referring to FIGS. 11A and 11B, after the formation of CESLs 70A and 70B, ILDs 72A and 72B are formed. The respective process is illustrated as process 228 in the process flow 200 as shown in FIG. 17. The ILDs 72A and 72B may be formed of a dielectric material, which may be deposited by any suitable conformal or bottom-up method, such as ALD, CVD, plasma-enhanced CVD (PECVD), or FCVD. The applicable dielectric material of the ILDs 72A and 72B may include SiOC, SiOCN, SiC, or the like.

ILDs 72A and 72B are formed by sharing common formation processes, and are formed of the same materials. In FIG. 11B, a dashed line is drawn to schematically mark where ILDs 72A and 72B are joined. It is appreciated that since ILDs 72A and 72B may be formed in the same continuous process, there may not be any distinguishable interface between ILDs 72A and 72B.

In accordance with alternative embodiments, ILDs 72A and 72B are formed in different formation processes, and may be formed of different materials. Accordingly, in FIG. 11B, dashed lines 75 (and dashed line 73) are drawn to schematically mark where the interface between ILDs 72A and 72B can be.

The formation of CESLs 70A and 70B and ILDs 72A and 72B includes depositing the corresponding dielectric layers, and performing a planarization process such as a CMP process or a mechanical grinding process to remove excess portions of the dielectric layers. In accordance with some embodiments, the mask layer 40 (FIG. 10A) is removed in the planarization process.

In accordance with some embodiments, the outer portions of ILDs 72A and 72B may seal the inner portions pre-maturely, and voids (also referred to as seams or air gaps) 120 may be left at the centers (FIG. 11A) of ILDs 72A. The voids 120 may be in the middle between the top portions and the bottom portions of CESLs 70A. Voids 120 may be elongated (FIG. 11B), with lengthwise directions extending horizontally, and may have a lateral maximum dimension (maximum width) and a vertical maximum dimension (maximum height) smaller than the lateral maximum dimension. In accordance with alternative embodiments, ILDs 72A have no voids formed therein. There may be, or may not be voids 121 (FIG. 11A) formed in ILDs 72B. When voids 121 are formed in ILD 72B, the voids 121, which may be seams, may be elongated and have lengthwise directions extending vertically.

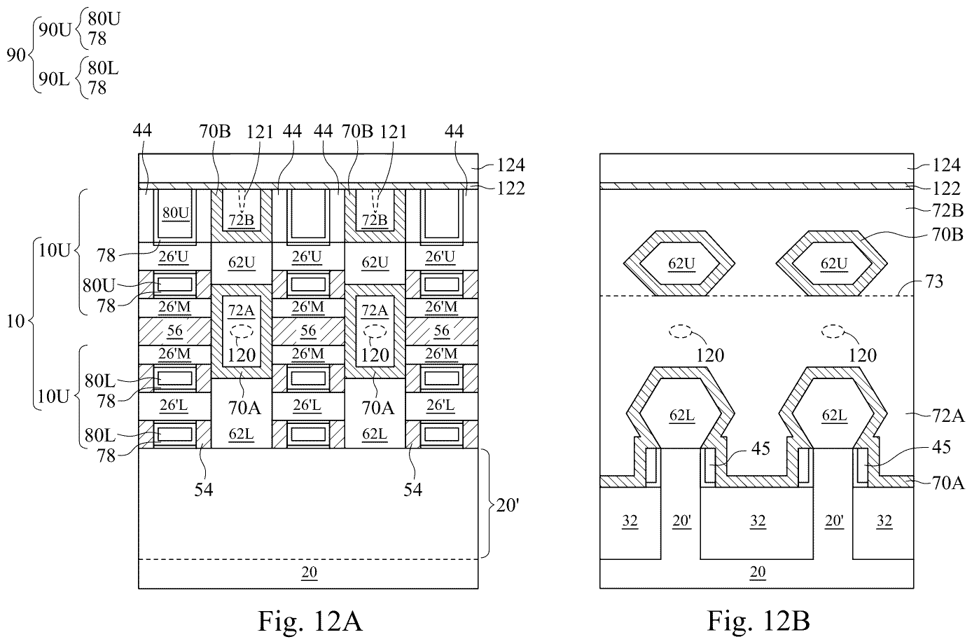

FIGS. 12A and 12B illustrate the formation of replacement gate stacks 90. The respective process is illustrated as process 230 in the process flow 200 as shown in FIG. 17. In the formation of replacement gate stacks 90, the dummy gate stacks 42 are first removed in one or more etching processes, so that recesses (not shown, occupied by gate stacks 90 as shown in FIG. 12A) are formed.

The remaining portions of the dummy nanostructures 24′A (FIG. 11A) are then removed through etching, so that the recesses extend between the semiconductor nanostructures 26′. In the etching process, the dummy nanostructures 24′A are etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

Gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′. Each of the gate dielectrics 78 may include an interfacial layer, which may include an oxide such as silicon oxide. The interfacial layer may be formed through a thermal oxidation process, a chemical oxidation process, and/or a deposition process. The gate dielectrics 78 may also include high-k dielectric layers, which have a high dielectric constant (high-k) value greater than, for example, about 7.0. High-k dielectric layers may be formed of or comprise a metal oxide or a silicate of a metal selected from hafnium, zirconium, barium, titanium, lead, and combinations thereof.

Gate electrodes 80L and 80U are also formed. In the formation process, conductive layers are first formed on the high-k dielectric layer, and the remaining portions of the recesses are filled. Each of gate 80L and 80U may include a metal-containing material such as TiN, TaN, TiAl, TiAlC, cobalt, ruthenium, aluminum, tungsten, combinations thereof, and/or multilayers thereof. The gate electrodes 80L and 80U may provide work-functions suitable to the resulting lower FETs (lower transistors) 10L and upper FETs (upper transistors) 10U. The gate electrodes 80L and 80U may be common gate electrodes formed in a same formation process, or may be electrically disconnected from each other and formed in separate formation processes.

Gate dielectrics 78 and gate electrodes 80L collectively form gate stacks 90L. Gate dielectrics 78 and gate electrodes 80U collectively form gate stacks 90U. CFET 10, which includes upper FETs 10U and lower FETs 10L, are thus formed.

Etch stop layer 122 and ILD 124 are then formed. Etch stop layer 122 may be formed of or comprise AlO, AlN, SiOC, or the like, or multilayers thereof. ILD 124 may be formed of or comprise SiO, SiOC, SiOCN, or the like.

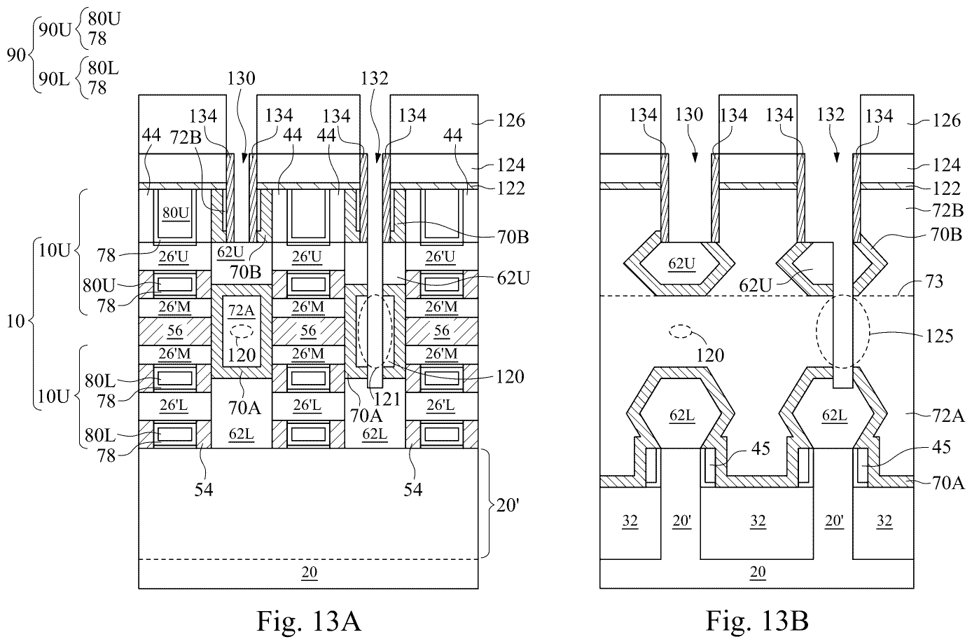

Referring to FIGS. 13A and 13B, a patterned etching mask 126 is formed over ILD 124, and is patterned. The patterned etching mask 126 may comprise a photoresist, and may comprise a bottom anti-reflective coating (BARC).

Etch stop layer 122 and ILD 124 are then patterned through etching using the patterned etching mask 126 to define patterns. Contact openings 130 and 132 are thus formed. The respective process is illustrated as process 232 in the process flow 200 as shown in FIG. 17. In the formation of contact openings 130 and 132, the second ILD 72B and the second CESL 70B are etched, so that the upper source/drain regions 62U are exposed. In the formation of contact opening 132, some parts of the upper source/drain regions 62U are also etched-through, followed by the etching of the underlying first ILD 72A and first CESL 70A. The etching for forming contact opening 132 stops on the top surface of the lower epitaxy source/drain region 62L.

While one etching mask 126 is illustrated, the etching may be performed through one etching mask or a plurality of etching masks to achieve the desirable pattern. For example, one etching mask (such as the illustrated etching mask 126) may be used to etch some portions of the second ILD 72B and second CESL 70B so that the top surfaces of some portions of the upper source/drain region 62U are exposed. Another etching mask (not shown) may be used to etch-through the upper source/drain region 62U, with the etching stopping on the lower source/drain region 62L. After the etching, etching mask 126 may be removed.

Further referring to FIGS. 13A and 13B, dielectric liners 134 are formed. The respective process is illustrated as process 234 in the process flow 200 as shown in FIG. 17. While FIGS. 13A and 13B illustrate etching mask 126 and dielectric liners 134 in the same figure, at the time dielectric liners 134 are formed, etching mask 126 may have been removed.

In accordance with some embodiments, the formation of dielectric liners 134 includes depositing a first conformal layer through a first conformal deposition process, for example through ALD, CVD, PVD, or the like. An anisotropic etching process is then performed to remove the horizontal portion of the first conformal layer, leaving the vertical portions as the dielectric liners 134. The material of the dielectric liners 134 may include SiN, SiON, a metal oxide of a metal such as Hf, Ti, Al, W, Nb, Re, or the like, a metal nitride of a metal such as Hf, Ti, Al, W, Nb, Re, or the like, or combinations thereof.

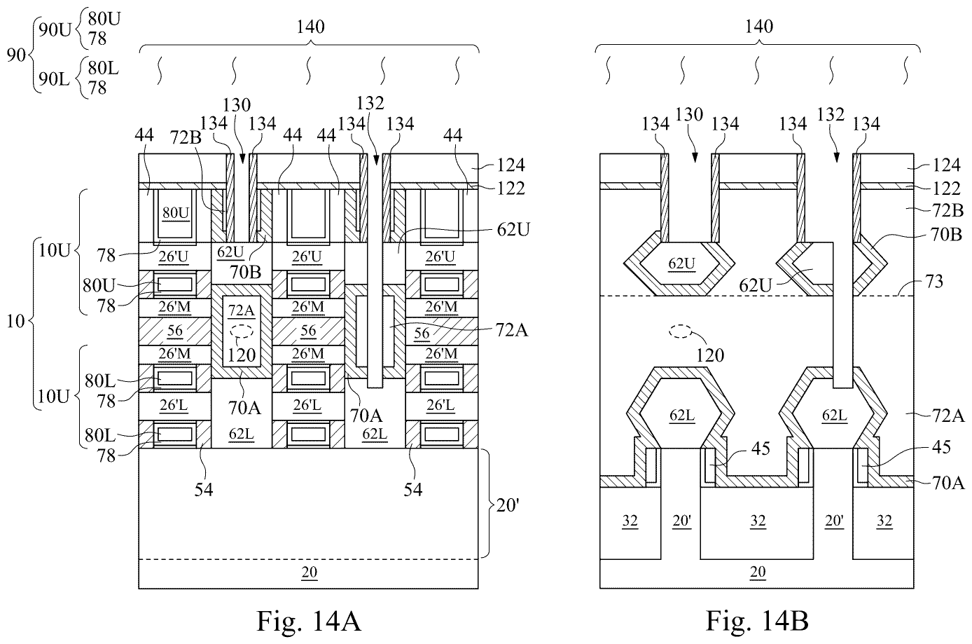

Referring to FIGS. 14A and 14B, after the formation of contact openings 130 and 132, a (wet) pre-clean process 140 is performed. The respective process is illustrated as process 236 in the process flow 200 as shown in FIG. 17. The pre-clean process 140 may be performed using a chemical that may effectively remove the residues in contact openings 130 and 132, but does not attack both of upper epitaxy source/drain regions 62U and lower epitaxy source/drain regions 62U. For example, diluted hydrofluoric acid, which is aqueous, may be used.

The chemical also does not attack the second ILD 72B and the first ILD 72A. It is appreciated that a portion of the first ILD 72A (in dashed region 125) has sidewalls exposed to contact opening 132. If the dummy ILD 66 is not replaced with ILD 72A, the chemical attacks the material of the ILD 66 (which would not be dummy), such as silicon oxide. The (dummy) ILD 66 thus will suffer from the lateral etching during the pre-clean process 140, and contact opening 132 will adversely expand laterally in region 125. As a result of the lateral etching, the subsequently formed contact plug 144A will laterally expand undesirably in the dashed region 125.

By removing dummy ILD 66 and replace with first ILD 72A, the first ILD 72A may be formed of the material (such as SiOC) that is not etched during the pre-clean process 140. Accordingly, the adverse lateral etching is avoided or mitigated.

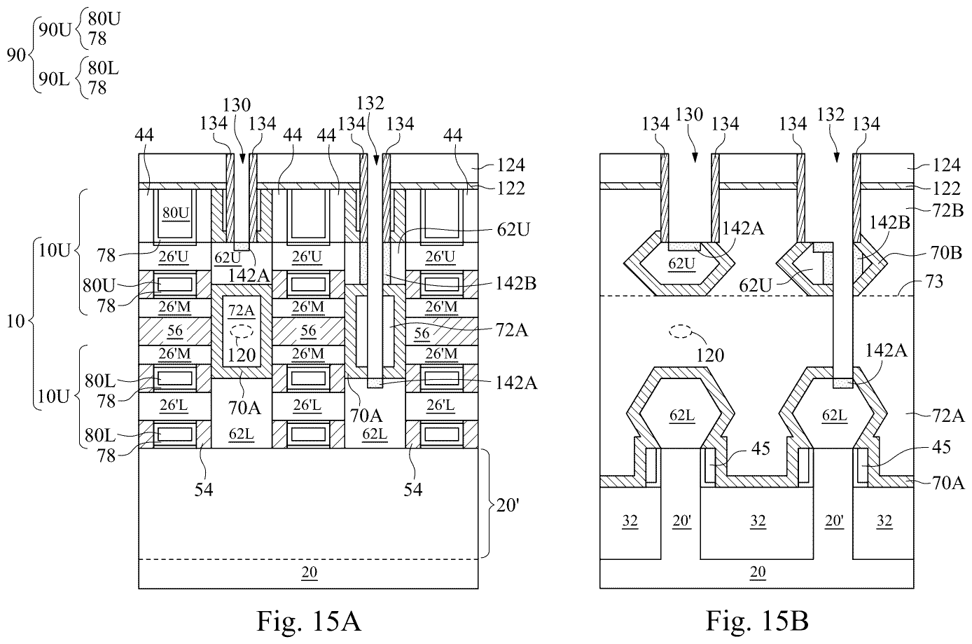

FIGS. 14A and 14B illustrate the structure with the etching mask 126 being removed. Referring to FIGS. 15A and 15B, silicide layers 142A are formed on the top surfaces of lower source/drain regions 62L and upper source/drain regions 62U, and silicide layer 142B are formed on the sidewalls of upper source/drain region 62U. The respective process is illustrated as process 238 in the process flow 200 as shown in FIG. 17.

The formation process may include depositing a metal layer (not shown), for example, using a conformal deposition process such as Physical Vapor Deposition (PVD). An annealing process is then performed to react the metal layer with the silicon (and silicon germanium) in upper source/drain regions 62U and lower source/drain regions 62L. Source/drain silicide layers 142A and 142B are thus formed. The annealing process may be performed through Rapid Thermal Anneal (RTA), furnace anneal, or the like. The remaining metal layer may then be removed, for example, in an anisotropic etching process.

In accordance with some embodiments, the part of upper source/drain regions 62U (FIG. 15B) on the right side of the illustrated rightmost silicide layer 142B may be fully silicided. This may occur when the thickness of the respective part of upper source/drain regions 62U has a small thickness, for example, smaller than about 3 nm. Alternatively, when the part of upper source/drain regions 62U on the right side of the rightmost silicide layer 142B has a greater thickness, for example, greater than about 3 nm, the corresponding part of the upper source/drain region 62U may have some portion remaining after the silicidation.

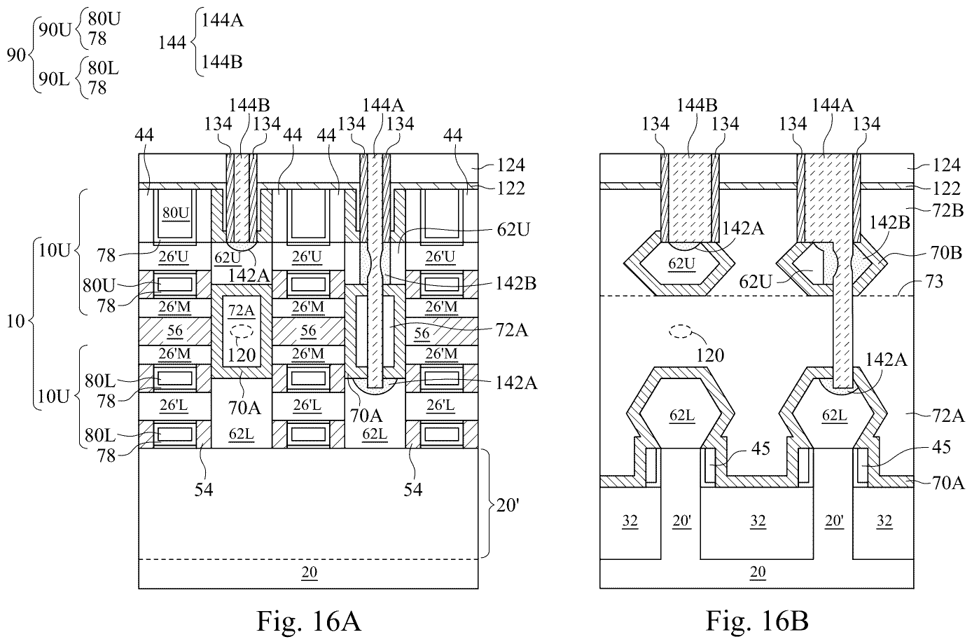

Next, as shown in FIGS. 16A and 16B, contact plugs 144A and 144B are formed, which are individually and collectively referred to as contact plugs 144. The respective process is illustrated as process 240 in the process flow 200 as shown in FIG. 17. In accordance with some embodiments, contact plugs 144A and 144B comprise a metal such as tungsten, molybdenum, ruthenium, iridium, or the like, or alloys thereof.

In accordance with some embodiments, contact plugs 144A and 144B have a single-layer structure, with the entire contact plugs 144A and 144B being formed of a homogeneous material such as aforementioned. In accordance with alternative embodiments, the formation of contact plugs 144A and 144B may include forming a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof.

Further referring to FIGS. 16A and 16B, after the deposition of the material for forming contact plugs 144A and 144B, a planarization process such as a CMP process or a mechanical grinding process is performed to remove excess portions of the deposited material(s), leaving contact plugs 144A and 144B. The contact plug 144B and the top portion of contact plug 144A are thus encircled by the dielectric liners 134. The top surfaces of contact plugs 144A and 144B and dielectric liners 134 are coplanar, and may further be coplanar with the top surface of dielectric layer 124.

Contact plug 144B is electrically connected to upper source/drain region 62U. Contact plug 144A is used as a local interconnect that electrically interconnects lower source/drain region 62L and upper source/drain region 62U. The formation of sidewall silicide layer 142B may cause a part of the contact plug 144A to be narrower than other parts, which is referred to as the necking of contact plug 144A. The necking may be caused by the nature of silicidation, wherein the center part of a silicon-containing layer may be silicided faster than the edge portions. In accordance with some embodiments, the part of contact plug 144A having the necking may have a width in the range between about 10 nm and about 13 nm, and the part of contact plug 144A over and lower the necking portion may have a width in the range between about 15 nm and about 20 nm.

In a cross-section of the upper source/drain regions 62U and lower source/drain regions 62L, as shown in FIG. 16A, contact plugs 144A and 144B are formed, so that voids 121 (FIG. 12A) no longer exist. Contact plugs 144A and 144B, however, may not expand to all the length of these upper source/drain regions 62U and lower source/drain regions 62L. Accordingly, FIG. 12A also illustrates a cross-section of the final structure, which final structure is shown in FIGS. 16A and 16B. The cross-section of FIG. 12A is parallel to the cross-section of FIG. 16A, except that the contact plugs 144A and 144B do not expand into the cross-section as shown in FIG. 12A, and thus voids 121 can still be seen in the cross-section of FIG. 12A.

In the embodiments in which some residue portions of dummy CESL 66 are left at corner regions 65 (also refer to FIG. 9A), the residue portions of dummy CESL 66 may be in contact with lower source/drain regions 62L and the first CESL 70A, and may be in contact with inner spacers 54 and/or middle semiconductor nanostructure 26′M. The material of the residue portions of dummy CESL 66 may be the same as or different from the material of the first CESL 70A.

The embodiments of the present disclosure have some advantageous features. By forming a dummy ILD and forming a lower (first) ILD using a dielectric material different from the dielectric material of the dummy ILD, the lower ILD may be formed of the material (such as SiOC) that is not etched during the pre-clean process. Accordingly, the adverse lateral etching of the lower ILD is less likely to occur.

In accordance with some embodiments of the present disclosure, a method comprises forming a first semiconductor layer and a second semiconductor layer overlapping the first semiconductor layer, wherein the second semiconductor layer is spaced apart from the first semiconductor layer by a dielectric isolation layer; performing a first epitaxy process to form a lower source/drain region aside of the first semiconductor layer; forming a dummy contact etch stop layer over the lower source/drain region; forming a dummy inter-layer dielectric over the dummy contact etch stop layer; performing a second epitaxy process to form an upper source/drain region aside of the second semiconductor layer, wherein the upper source/drain region is over the dummy inter-layer dielectric; removing the dummy inter-layer dielectric and the dummy contact etch stop layer to form a gap between the upper source/drain region and the lower source/drain region; and forming a dielectric region to fill the gap. In an embodiment, the dielectric region comprises a first contact etch stop layer; and a first inter-layer dielectric, wherein in a cross-section of the first inter-layer dielectric, the first inter-layer dielectric is encircled by the first contact etch stop layer.

In an embodiment, the method further comprises forming a second contact etch stop layer over the upper source/drain region, wherein the second contact etch stop layer is formed in a same process as for forming the first contact etch stop layer; and forming a second inter-layer dielectric in a same process as for forming the first inter-layer dielectric. In an embodiment, the dummy inter-layer dielectric is formed of a first dielectric material, and the first inter-layer dielectric is formed of a second dielectric material different from the first dielectric material.

In an embodiment, the method further comprises forming a contact opening, and a portion of the contact opening in the first inter-layer dielectric has a first width; and performing a pre-clean process to clean the contact opening using a chemical, wherein after the pre-clean process, the portion of the contact opening in the first inter-layer dielectric has a second width same as the first width. In an embodiment, the method further comprises, after the pre-clean process, forming silicide layers on the upper source/drain region and the lower source/drain region; and filling the contact opening with a contact plug.

In an embodiment, the dummy inter-layer dielectric comprises silicon oxide, and the dielectric region comprises silicon oxy-carbide. In an embodiment, the forming the dummy contact etch stop layer and the forming the dielectric region comprise flowable chemical vapor deposition processes. In an embodiment, the method further comprises, after the dielectric region is formed, removing a dummy semiconductor layer between the first semiconductor layer and the second semiconductor layer to leave a space; and forming a replacement gate stack in the space.

In accordance with some embodiments of the present disclosure, a method comprises forming a lower source/drain region aside of a first semiconductor layer; forming a dummy region over the lower source/drain region; forming an upper source/drain region aside of a second semiconductor layer, wherein the second semiconductor layer overlaps, and is spaced apart from, the first semiconductor layer; removing the dummy region to form a gap between the upper source/drain region and the lower source/drain region; forming a first contact etch stop layer and a second contact etch stop layer, wherein the first contact etch stop layer is between the upper source/drain region and the lower source/drain region, and the second contact etch stop layer is over the upper source/drain region.

A first inter-layer dielectric and a second inter-layer dielectric are then formed, wherein the first inter-layer dielectric is in the first contact etch stop layer, and the second inter-layer dielectric is over the second contact etch stop layer; performing an etching process to form a contact opening, wherein the second inter-layer dielectric, the second contact etch stop layer, the first inter-layer dielectric, and the first contact etch stop layer are etched; performing a pre-clean process to clean the contact opening; forming silicide layers on the upper source/drain region and the lower source/drain region; and filling the contact opening with a contact plug.

In an embodiment, the forming the dummy region comprises depositing a dummy contact etch stop layer over the lower source/drain region; and depositing a dummy inter-layer dielectric over the dummy contact etch stop layer. In an embodiment, the dummy region and the first inter-layer dielectric are formed of different dielectric materials. In an embodiment, the pre-clean process is performed using a chemical that is configured to etch the dummy region, and not to etch the first inter-layer dielectric.

In an embodiment, the pre-clean process is performed using hydrofluoric acid, and wherein the dummy region comprises silicon oxide, and the first inter-layer dielectric comprises silicon oxy-carbide. In an embodiment, in a cross-sectional view of the first contact etch stop layer, the first contact etch stop layer forms a ring encircling the first inter-layer dielectric.

In accordance with some embodiments of the present disclosure, a structure comprises a first semiconductor layer; a second semiconductor layer overlapping the first semiconductor layer; a lower source/drain region aside of the first semiconductor layer; an upper source/drain region aside of the second semiconductor layer; a first contact etch stop layer between the lower source/drain region and the upper source/drain region, wherein in a vertical cross-section of the first contact etch stop layer, the first contact etch stop layer forms a ring; a first inter-layer dielectric encircled by the ring; a second contact etch stop layer over the upper source/drain region; and a second inter-layer dielectric over the second contact etch stop layer.

In an embodiment, the first contact etch stop layer and the second contact etch stop layer comprise a same first dielectric material, and the first inter-layer dielectric and the second inter-layer dielectric comprise a same second dielectric material. In an embodiment, the first contact etch stop layer comprises an upper horizontal portion contacting a bottom surface of the upper source/drain region; and a lower horizontal portion contacting a top surface of the lower source/drain region. In an embodiment, the first inter-layer dielectric comprises a void therein. In an embodiment, the void is in a middle of the inter-layer dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor layer and a second semiconductor layer overlapping the first semiconductor layer, wherein the second semiconductor layer is spaced apart from the first semiconductor layer by a dielectric isolation layer;
performing a first epitaxy process to form a lower source/drain region aside of the first semiconductor layer;
forming a dummy contact etch stop layer over the lower source/drain region;
forming a dummy inter-layer dielectric over the dummy contact etch stop layer;
performing a second epitaxy process to form an upper source/drain region aside of the second semiconductor layer, wherein the upper source/drain region is over the dummy inter-layer dielectric;
removing the dummy inter-layer dielectric and the dummy contact etch stop layer to form a gap between the upper source/drain region and the lower source/drain region; and
forming a dielectric region to fill the gap.

2. The method of claim 1, wherein the dielectric region comprises:
a first contact etch stop layer; and
a first inter-layer dielectric, wherein in a cross-section of the first inter-layer dielectric, the first inter-layer dielectric is encircled by the first contact etch stop layer.

3. The method of claim 2 further comprising:
forming a second contact etch stop layer over the upper source/drain region, wherein the second contact etch stop layer is formed in a same process as for forming the first contact etch stop layer; and
forming a second inter-layer dielectric in a same process as for forming the first inter-layer dielectric.

4. The method of claim 2, wherein the dummy inter-layer dielectric is formed of a first dielectric material, and the first inter-layer dielectric is formed of a second dielectric material different from the first dielectric material.

5. The method of claim 2 further comprising:
forming a contact opening, and a portion of the contact opening in the first inter-layer dielectric has a first width; and
performing a pre-clean process to clean the contact opening using a chemical, wherein after the pre-clean process, the portion of the contact opening in the first inter-layer dielectric has a second width same as the first width.

6. The method of claim 5 further comprising, after the pre-clean process:
forming silicide layers on the upper source/drain region and the lower source/drain region; and
filling the contact opening with a contact plug.

7. The method of claim 1, wherein the dummy inter-layer dielectric comprises silicon oxide, and the dielectric region comprises silicon oxy-carbide.

8. The method of claim 1, wherein the forming the dummy contact etch stop layer and the forming the dielectric region comprise flowable chemical vapor deposition processes.

9. The method of claim 1 further comprising:
after the dielectric region is formed, removing a dummy semiconductor layer between the first semiconductor layer and the second semiconductor layer to leave a space; and
forming a replacement gate stack in the space.

10. A method comprising:
forming a lower source/drain region aside of a first semiconductor layer;
forming a dummy region over the lower source/drain region;
forming an upper source/drain region aside of a second semiconductor layer, wherein the second semiconductor layer overlaps, and is spaced apart from, the first semiconductor layer;
removing the dummy region to form a gap between the upper source/drain region and the lower source/drain region;
forming a first contact etch stop layer and a second contact etch stop layer, wherein the first contact etch stop layer is between the upper source/drain region and the lower source/drain region, and the second contact etch stop layer is over the upper source/drain region;
forming a first inter-layer dielectric and a second inter-layer dielectric, wherein the first inter-layer dielectric is in the first contact etch stop layer, and the second inter-layer dielectric is over the second contact etch stop layer;
performing an etching process to form a contact opening, wherein the second inter-layer dielectric, the second contact etch stop layer, the first inter-layer dielectric, and the first contact etch stop layer are etched;
performing a pre-clean process to clean the contact opening;
forming silicide layers on the upper source/drain region and the lower source/drain region; and
filling the contact opening with a contact plug.

11. The method of claim 10, wherein the forming the dummy region comprises:
depositing a dummy contact etch stop layer over the lower source/drain region; and
depositing a dummy inter-layer dielectric over the dummy contact etch stop layer.

12. The method of claim 10, wherein the dummy region and the first inter-layer dielectric are formed of different dielectric materials.

13. The method of claim 10, wherein the pre-clean process is performed using a chemical that is configured to etch the dummy region, and not to etch the first inter-layer dielectric.

14. The method of claim 10, wherein the pre-clean process is performed using hydrofluoric acid, and wherein the dummy region comprises silicon oxide, and the first inter-layer dielectric comprises silicon oxy-carbide.

15. The method of claim 10, wherein in a cross-sectional view of the first contact etch stop layer, the first contact etch stop layer forms a ring encircling the first inter-layer dielectric.

16. A structure comprising:
a first semiconductor layer;
a second semiconductor layer overlapping the first semiconductor layer;
a lower source/drain region aside of the first semiconductor layer;
an upper source/drain region aside of the second semiconductor layer;
a first contact etch stop layer between the lower source/drain region and the upper source/drain region, wherein in a vertical cross-section of the first contact etch stop layer, the first contact etch stop layer forms a ring;
a first inter-layer dielectric encircled by the ring;
a second contact etch stop layer over the upper source/drain region; and
a second inter-layer dielectric over the second contact etch stop layer.

17. The structure of claim 16, wherein the first contact etch stop layer and the second contact etch stop layer comprise a same first dielectric material, and the first inter-layer dielectric and the second inter-layer dielectric comprise a same second dielectric material.

18. The structure of claim 16, wherein the first contact etch stop layer comprises:
an upper horizontal portion contacting a bottom surface of the upper source/drain region; and
a lower horizontal portion contacting a top surface of the lower source/drain region.

19. The structure of claim 16, wherein the first inter-layer dielectric comprises a void therein.

20. The structure of claim 19, wherein the void is in a middle of the inter-layer dielectric.
